(19) United States
(12) Patent Application Publication
(10) Pub. No.: US 2026/0316227 A1
(43) Pub. Date: Oct. 15, 2026

(54) OPERATING TOOL FOR ACTUATING A COLLET NUT

(71) Applicant: ZOLLMANN GMBH, Burladingen (DE)

(72) Inventor: Martin ZOLLMANN, Burladingen (DE)

(21) Appl. No.: 19/632,297

(22) Filed: Mar. 29, 2026

(30) Foreign Application Priority Data
Apr. 14, 2025 (EP) 25170323.7
Jun. 12, 2025 (EP) 25182472.8

(51) Int. Cl. B25B 13/06; B25B 13/08; B25B 13/48

(52) U.S. Cl. CPC B25B 13/06; B25B 13/08; B25B 13/48

(57) ABSTRACT

An operating tool (100; 200; 400) for actuating a collet nut is proposed, wherein the operating tool (100; 200; 400) has a terminal annular receiving area for gripping the collet nut. The terminal annular receiving area comprises a plurality of grooves (101), which run from the outside inward, and lugs (102) which lie between the grooves. The side flanks of the lugs (102) delimited by the grooves (101) are respectively provided with an undercut profile. The terminal annular receiving area has a centring edge (150; 250), which protrudes beyond the plane of the base surface of the grooves (101).

The present invention relates to an operating tool for actuating a collet nut according to the preamble of claim 1. The invention furthermore relates to a clamping system, which comprises at least one such operating tool.

### THE PRIOR ART

Collet nuts are used, for example, to clamp collets, which are used to clamp tool shafts in the tool holder of a machine tool. Particular precautions must be taken, in particular when there is limited space and access to the collet nut is tight, so that the necessary clamping force can be exerted. Conventionally, clamping is done with the help of a wrench, which is, for example, equipped with pins, which engage in hole-like depressions of the collet nut, and therefore the collet nut can be clamped with the help of the wrench. German utility model document DE 296 08 677 U1 describes, for example, a collet nut with elongated hole-like depressions for engaging the pins of a wrench.

To avoid the possibility of the wrench slipping, European patent application EP 1 052 047 A2 describes a collet nut, which provides groove-shaped depressions for engaging the pins arranged on a collet chuck. The grooves are designed with a dovetail cross section, so that the wrench is prevented from slipping by the pins of the wrench, which have a complementary profile, engaging behind in the undercut of the grooves.

German utility model document DE 201 19 008 U1 likewise proposes a clamping system in which the grooves arranged on the end face of the collet nut have a dovetail cross section. The inner edges of the grooves extend in a radial direction, such that the grooves taper evenly towards the centre of the collet nut. The system furthermore comprises a wrench with a wrench head, which has correspondingly formed lugs to engage in the grooves of the collet nut. This system is intended to prevent the wrench from tipping and sliding out, and to prevent the associated risk of breakage and slipping when the collet nut is actuated.

Other forms of undercut with comparable collet nuts have also already been described. Thus, the German laid-open application DE 103 02 529 A1 discloses a comparable collet nut in which the grooves have an S-shaped profile as undercut. The undercut profile of the grooves can stabilise the nut on the wrench to a certain extent, however the nut cannot be completely prevented from slipping sideways out of the wrench.

German patent application DE 10 2009 006 520 A1 describes a clamping system, having a collet nut and a wrench, wherein the collet nut has recesses on its end face, which are provided to receive projections of the wrench. The recesses are either located on the outer edge or the inner edge of the collet nut, with the respective opposite edge, i.e. the inner edge or the outer edge, being closed. As a result, the projections of the wrench can either engage from the outside, or from the inside, and be inserted into the recesses of the collet nut. The recesses of the collet nut are provided with at least one undercut which the projections of the wrench can grip from behind or from underneath. This ensures a slip-free engagement of the wrench. In particular, the collet nut cannot fall out of the wrench due to the undercut.

In addition to a conventional wrench with an elongated basic shape and a wrench head equipped with appropriate geometries for engagement with the structures of the collet nut, other wrench shapes or generally other operating tools can also be used for clamping and loosening such collet nuts. In this context, sockets especially, in particular torque nuts, play a significant role.

A socket generally describes a tool part that creates a connection between a wrench, for example a ratchet wrench, and the respective nut, screw or other screw connection element. A receiver for connecting to the wrench, for example a hexagon head or a square socket, is formed on one of the sides of the socket. On the other side of the socket, a geometry is provided, which is adapted to the shape of the nut, screw or other screw connection element that is to be gripped.

The aforementioned DE 10 2009 006 520 A1 also discloses a socket, having a hexagon head at one end. The projections mentioned above, which are intended to engage in the correspondingly formed recesses of the collet nut, are formed at the other end.

Another, often helpful operating tool for collet nuts is the so-called screwing aid, which is likewise formed with, for example, one hexagon head and on the other side with a geometry for gripping the collet nut. Compared to the socket, a screwing aid is generally shorter.

The described system of DE 10 2009 006 520 A1 provides a satisfactory solution for many applications, which enables a user-friendly and safe actuation of a clamp system. Nonetheless, there is always a need for alternative systems.

Against this background, the object of the invention is to provide an operating tool for working with a collet nut. The operating tool should have a simple construction and yet enable slip-free and secure use and clamping of a collet nut with minimal application of force.

### DISCLOSURE OF THE INVENTION

This object is solved by an operating tool for actuating a collet nut, as described in claim 1. The object is furthermore solved by a clamping system, as follows from the further, independent claim. Preferred embodiments of the operating tool result from the subclaims.

The operating tool is initially characterised in that it does not have an external and/or internal thread. It is intended for actuation of, or for working with, a collet nut, whereby the collet nut itself can be used to clamp a collet, which can be intended for clamping tool shafts in the tool holder of a machine tool.

The collet nut itself usually has an annular shape and is provided with an external or internal thread. The thread generally serves to screw the collet nut into a receptacle of a machine tool spindle or of a tool. Furthermore, the collet nut may be provided in a conventional manner with an inner cone for the centred gripping of a collet.

The operating tool according to the invention has a terminal annular receiving area for gripping the collet nut. The terminal receiving area therefore has a plurality of grooves, which extend from the outside inwards. Lugs are formed between the grooves. The side flanks, bordered by the grooves and running from the outside inwards, of the lugs are respectively provided with an undercut profile.

The collet nut to be gripped has, in a corresponding manner, on that side, which is facing the operating tool, a plurality of lugs with grooves lying therebetween. The side flanks, running from the outside inwards, of the grooves are provided with a profile which allows the lugs of the operating tool to engage in the grooves and the operating tool to hook in.

The operating tool according to the invention for the collet nut is preferably a hollow cylindrical operating tool.

An essential aspect of the invention lies in the annular receiving area of the operating tool according to the invention having a centring edge which protrudes beyond the plane of the base surface of the grooves. This centring edge can significantly improve the stability of the connection between the collet nut and the respective operating tool compared to conventional systems. The centring edge facilitates and stabilises the gripping of the collet nut and the collet nut does not slip or fall off the operating tool.

The centring edge can be located in the inner region of the terminal annular receiving area or in the outer region of the terminal annular receiving area. In particularly preferable embodiments, the centring edge is located in the inner region of the terminal annular receiving area.

Preferably, the profile of the side flanks of the lugs of the operating tool is fitted to the profile of the grooves or the lugs of the collet nut in such a way that a form-locking engagement is achieved. Preferably, each profile is a complementary profile. Hereby, the connection between the operating tool and the collet nut can be particularly slip-proof, such that the collet nut is prevented particularly reliably from falling off the operating tool. Furthermore, the form-locking engagement enables a particularly efficient transfer of torque when clamping or releasing the collet nut.

It is, however, also possible that the profile of the side flanks of the lugs of the operating tool is not perfectly fitted to the profile of the grooves or of the side flanks of the lugs of the collet nut. Even in that case, the centring edge provided according to the invention successfully enables the collet nut to be reliably gripped by the operating tool.

In particularly preferred embodiments of the operating tool according to the invention, the undercut profile of the side flanks of the lugs of the operating tool is a rectangular profile. With particular advantage, in these embodiments, the collet nut is also provided with a corresponding rectangular profile in the side flanks of the lugs thereof. However, other undercut profiles in the side flanks of the lugs of the operating tool (and of the collet nut) are also possible, for example S-profiles or others.

In particularly preferred embodiments, 3-8 lugs, preferably six lugs, are provided in the terminal annular receiving area of the operating tool. Preferably, the lugs are evenly distributed around the circumference of the operating tool. It may be preferred that the side flanks of the lugs of the operating tool run radially inwards, such that the lugs, as well as the grooves, taper inwards.

In a particularly preferable manner, the operating tool is constructed from at least two parts. In these embodiments, the operating tool according to the invention comprises:
(i) a base body comprising the terminal annular receiving area having the grooves and the lugs, and
(ii) a hollow cylindrical centring ring, which forms the centring edge.

In the case of the centring edge in the inner region, the centring ring extends into the interior of the base body. In the case of the centring edge in the outer region, the centring ring extends on the outer circumference of the base body.

This embodiment of the operating tool according to the invention enables a particularly advantageous production of the operating tool. The base body can expediently be made of a hardened material, for example from hardened steel. Sufficient hardness of the materials is advantageous, since the base body and in particular the annular receiving area having the lugs can be subjected to great loads during torque transmission during clamping or loosening of the collet nut. The centring ring, on the other hand, is subjected to lesser loads, meaning that the use of a hardened material for the centring ring is of minor importance.

Furthermore, it is preferable if the operating tool, and in particular the base body, is coated or otherwise treated to protect against corrosion. For example, galvanizing of the steel may be provided as a material for the base body.

In particularly preferred embodiments, the centring ring is manufactured from stainless steel. Stainless steel is corrosion-resistant and long-lasting, meaning that it is very well suited as a material for the centring ring. In addition, the stainless steel centring ring can be manufactured in a particularly precise and accurately fitting manner. It can also be provided that the entire operating tool is manufactured from stainless steel. It can, however, also be advantageous, in particular for reasons of cost, to make the base body out of hardened steel and the centring ring out of stainless steel.

In other embodiments, the centring ring can, for example, be manufactured from other steel or non-ferrous metal or plastics material.

In a preferred embodiment of the operating tool according to the invention, the centring ring can be pressed to fit snugly on an inner, annularly extending shoulder of the base body. This design allows for a simple and very precise production of the operating tool with the internally arranged centring edge. In a comparable manner, a snug fit can also be used for the attachment of an outer centring edge.

However, it is also possible that the operating tool according to the invention can be manufactured as a single part, in which case the centring ring is therefore directly integrated into the base body.

The base body of the operating tool according to the invention, with or without integrated centring edge, can, for example, be manufactured as a cast part, in particular as a precision cast part. The structures of the base body in the region of the lugs and grooves of the receiving area can be produced, for example, by lost-wax or die-casting processes or, preferably, by computer-aided machining processes, for example on CNC machines. Furthermore, it is, for example, possible to make the operating tool with or without an integrated centring ring using 3D-printing.

In very particularly preferred embodiments of the operating tool according to the invention, the operating tool is characterised in that the outer termination of the centring edge is located below the plane of the outer surfaces of the lugs, i.e. the outer surfaces of the lugs in the axial direction. This means that the lugs are somewhat longer than the height of the centring edge. This design of the operating tool is based on the fact that a collet usually has a certain undersized tension. The reduced height of the centring edge and the resulting free space prevents the front of the collet from striking directly against the operating tool when the collet nut is tightened and thus from being blocked.

Depending on the dimensions of the clamping system, the outer termination of the centring edge can be set back in relation to the plane of the outer surfaces of the lugs, for example by between 0.5 and 1.0 mm. With a commercially standard clamping system, the centring edge of the operating tool can preferably be 0.4 - 0.6 mm, particularly preferably 0.5 mm, shorter than the height of the lugs.

In particularly preferred embodiments of the operating tool according to the invention, the end of the operating tool opposite the receiving area with the lugs is provided with a hexagon or square head or, for example, a square socket. The area having the hexagon head or square head or the square socket in particular serves as an application area for an operating tool, for example for a torque wrench.

In particularly preferred embodiments, the operating tool according to the invention is designed as a socket, wherein a more or less long shaft is provided between the receiving area with the lugs and the centring edge on one side and the area for application of an operating tool on the other side. The length of the socket, or the length of the shaft, is preferably adjusted to the respective use of the socket. The length of the socket depends in particular on the length of the tool shaft, which is to be clamped into a collet with the help of the operating tool.

Depending on the length of the socket, it may be advantageous if the socket is designed with weight-reducing features. In particular, three, four or more elongated holes may be provided in the shaft of the socket. In addition to the associated weight reduction, the elongated holes also have the advantage that the tool shaft running inside the socket is visible to the operator during the clamping process.

As a further weight-reducing measure, one or more milled cut-outs can be made, in particular on the shaft of the operating tool, for example as a circumferential tapering ring, said cut-outs reducing wall thickness and, with it, the weight of the socket.

In particularly preferred embodiments, the socket is designed as a torque nut. In this embodiment, the socket is provided to create the connection with a torque wrench. Preventing the torque nut from slipping from the collet nut as a result of the centring edge provided according to the invention makes it possible to work particularly safely with the torque nut. Additionally, the torque nut guarantees a certain distance between the operating person and the potentially sharp-edged tools of the machine tool and, in doing so, also reduces the risk of injury to the operating person.

In further preferred embodiments, the socket is designed as a multi-part socket, in particular as a modular socket. The multi-part socket comprises a base holder and a changeable part (operating element), wherein the changeable part comprises the terminal annular receiving area and the centring edge according to the above description.

Preferably, the changeable part (operating element) is connected to the base holder by means of a threaded union connection, in particular by means of a cam threaded union connection. The cam threaded union connection enables a particularly stable connection between the two elements.

The changeable part (operating element) having the terminal annular receiving area and the centring edge is subject to a certain degree of wear. In this embodiment, in the form of a multi-part socket, it is possible that only the changeable part, i.e. the wearing part, is replaced as needed. This has the advantage for the user that the entire socket need not be replaced. This embodiment thus presents the user with a very cost-effective solution.

Furthermore, the base holder can be designed in such a way that, with two or three base holder sizes together with, if necessary, several different changeable parts (operating elements), the entire range of collet nuts of different sizes can be used.

In other embodiments of the operating tool, the operating tool is a screwing aid. The screwing aid differs from the socket in particular in that the screwing aid has no distinct shaft and thus is generally shorter than the socket. When using the screwing aid, placing the collet nut on the collet can be made much easier, as the space for handling in the area of the collet is often narrow and difficult to reach by hand. After screwing in the collet nut with the help of the screwing aid, the torque nut can then be used so that the collet nut can be tightened effectively and without injury.

As further embodiments of the operating tool according to the invention, for example, extensions or plug-in sleeves can be designed to correspond to the above-described receiving area having grooves, lugs and a centring edge.

Furthermore, the invention comprises a clamping system for working with a collet or for clamping tool shafts using a collet. The system comprises at least one collet nut and at least one operating tool according to the above description. The operating tool is preferably designed as a socket or as a screwing aid. Preferably the system comprises both at least one socket and at least one screwing aid. Preferably, several sockets of various lengths are included in the system.

Furthermore, the system can optionally include one or more conventional wrenches, which are provided with corresponding lugs or projections on a partially circular wrench head for engagement with the corresponding structures of the collet nut. With such a wrench, the collet nut can be clamped or released by hand as needed.

Further features and advantages of the invention arise from the following description of exemplary embodiments in connection with the drawings. Each of the individual features can be realised individually or different features can be combined with each other.

### BRIEF DESCRIPTION OF THE DRAWINGS

### Shown in the drawings are

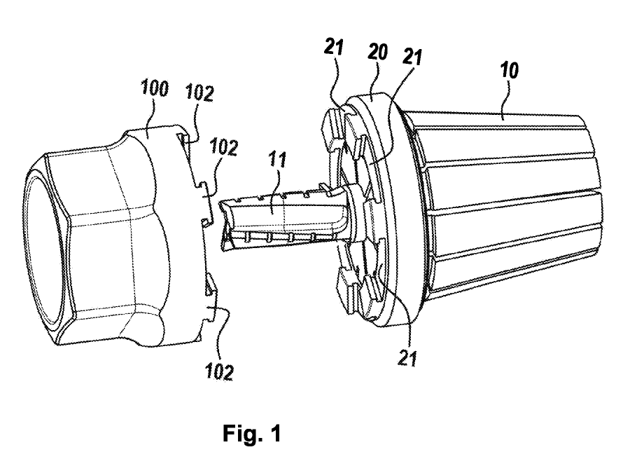

FIG. 1 an oblique view of a clamping system, having a collet, a collet nut and an operating tool according to the invention;

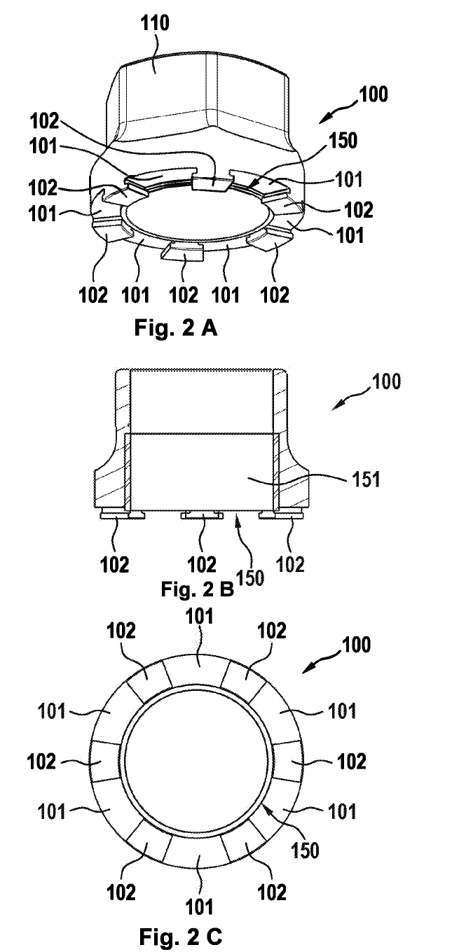

FIG. 2 an operating tool according to the invention in an embodiment as a screwing aid, having an internally located centring edge – oblique view from below (A), longitudinal section (B), view from below (C);

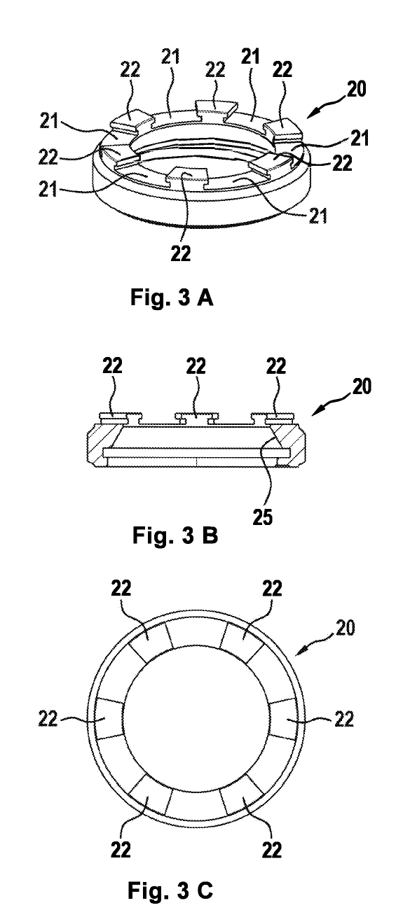

FIG. 3 a collet nut – oblique view from above (A), longitudinal section (B), view from above (C);

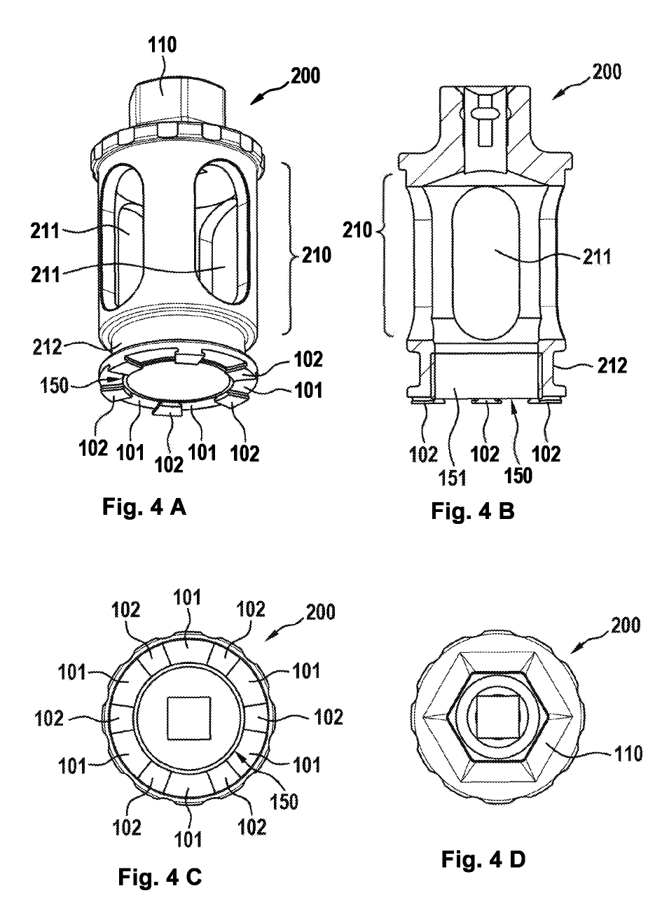

FIG. 4 an operating tool according to the invention in an embodiment as a socket – oblique view from below (A), longitudinal section (B), view from below (C), view from above (D);

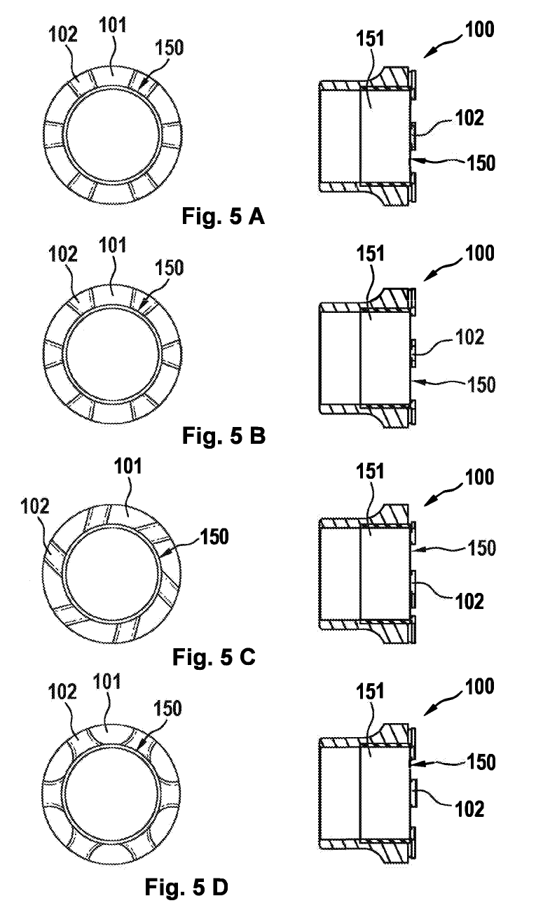

FIG. 5 an operating tool according to the invention in an embodiment as a screwing aid in various designs A - D, in each case in longitudinal section (right) and view from below (left);

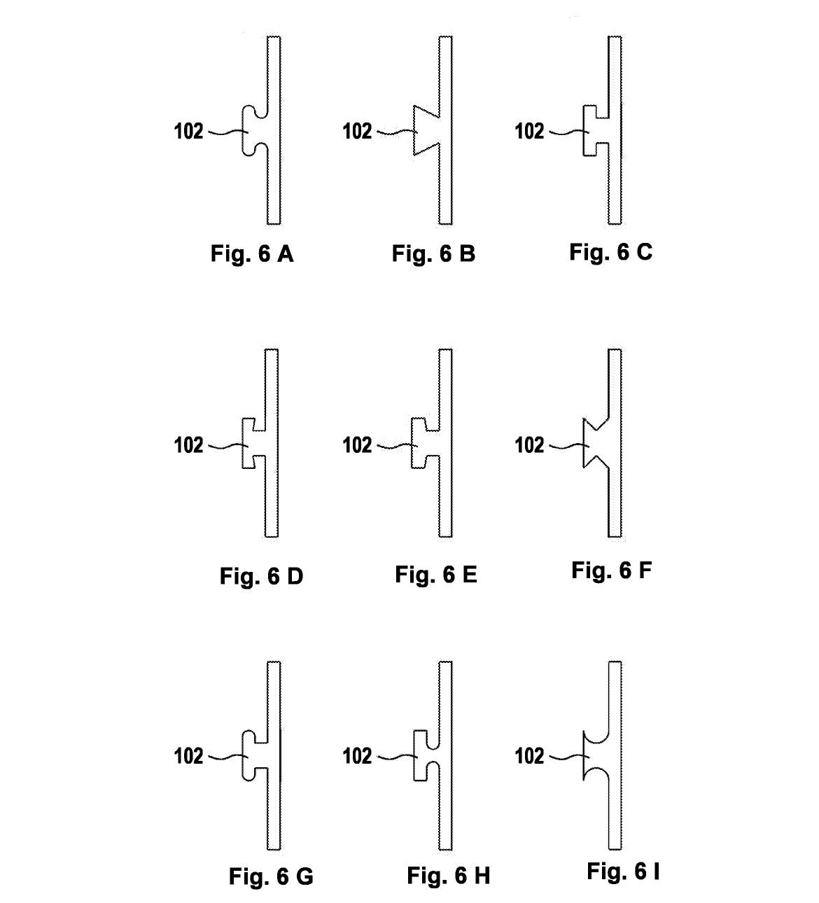

FIG. 6 various undercut profile shapes of the lugs (A - I) of the operating tool according to the invention;

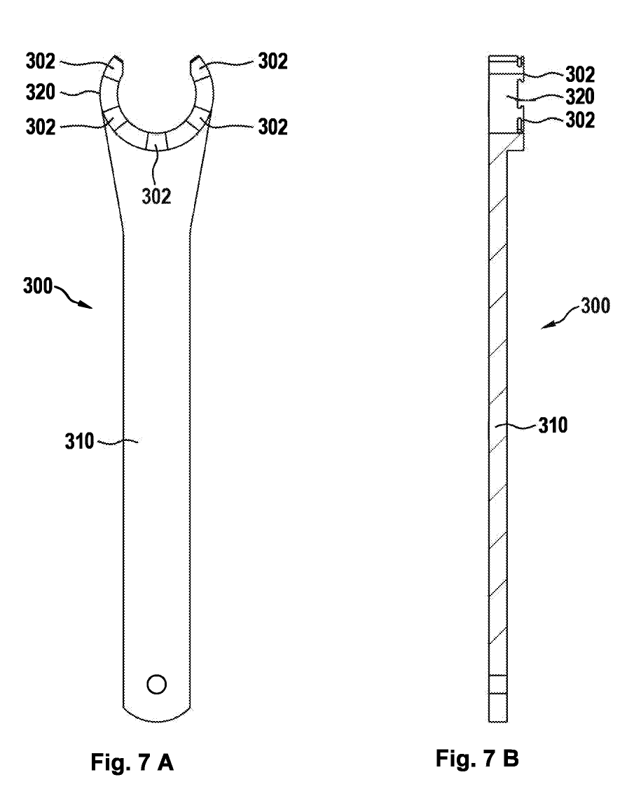

FIG. 7 a wrench viewed from below (A) and in longitudinal section (B);

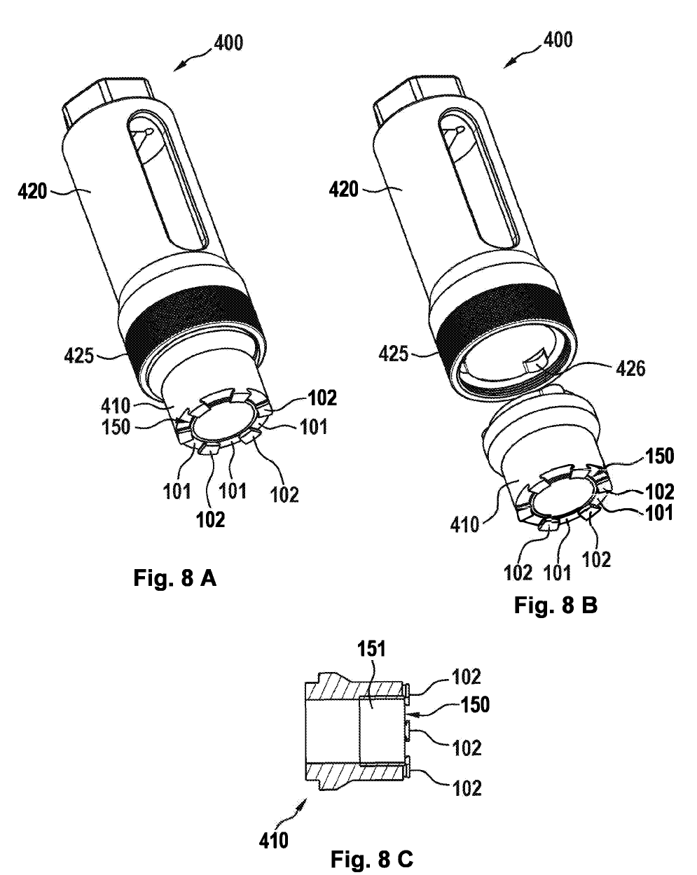

FIG. 8 an operating tool according to the invention in an embodiment as a modular socket, having a base holder and a changeable part in an oblique view of both of the parts in assembled form (A) and in separated form (B), as well as a section view of the changeable part in isolated form (C); and

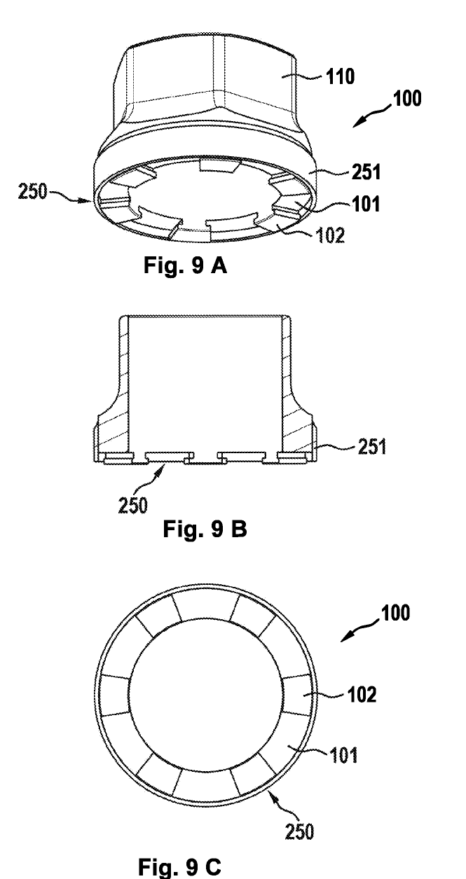

FIG. 9 an operating tool according to the invention in an embodiment as a screwing aid, having an externally located centring edge – oblique view from below (A), longitudinal section (B), view from below (C).

### EXEMPLARY EMBODIMENTS OF THE INVENTION

FIG. 1 shows a clamping system, having a collet 10 for clamping a tool shaft 11, a collet nut 20 and an operating tool 100 according to the invention. The operating tool 100 is designed in the form of a screwing aid. On the side facing the collet nut 20, the operating tool 100 is provided with a plurality of lugs 102. The lugs 102 have an undercut profile on their respective side flanks extending from the outside inwards. The lugs 102 of the operating tool 100 are provided for form-locking engagement in corresponding grooves 21 of the collet nut 20, so that the operating tool 100 can engage with the collet nut 20 and efficient torque transmission is possible.

Further details of the operating tool 100 according to the invention emerge from FIG. 2. The oblique view from below shown in sub-figure A shows the six lugs 102 in the lower annular receiving area of the operating tool 100. Six grooves 101 extend between the lugs 102. The respective side flanks of the lugs 102, extending from the outside inwards, have an undercut profile, in this case a rectangular profile.

A hexagon head 110 is formed on the side of the operating tool 100 opposite the receiving area. The operating tool 100 can be actuated via the hexagon head 110 using an appropriate wrench. Alternatively, the operating tool 100, in particular in this design as a screwing aid, can also be gripped by hand in the area of the hexagon head 110.

As an essential feature of the invention, the operating tool 100 is equipped with an inner centring edge 150. The centring edge 150 protrudes beyond the plane of the base surface of the grooves 101. The centring edge 150 prevents the operating tool 100 from slipping sideways and/or being misaligned when it is placed on and when it grips the collet nut. The centring edge 150 thus significantly facilitates and stabilises the placement of the operating tool 100 on the collet nut and the connection of same thereto. Compared to conventional clamping systems, the handling of the system can be improved by way of the operating tool 100 according to the invention and the risk of injury to the operator can be reduced.

Sub-figure B of FIG. 2 shows a longitudinal section through the operating tool 100. The two-part design can be seen with the centring ring 151 pressed into the interior of the hollow cylindrical operating tool 100 by a snug fit. The pressed-in centring ring 151 forms the centring edge 150. The centring edge 150 protrudes beyond the plane of the base surface of the grooves 101. The height of the centring edge 150 is somewhat lower than the height of the lugs 102.

Sub-figure C of FIG. 2 shows a view of the underside of the operating tool 100 having the lugs 102, the grooves 101 lying therebetween, as well as the inner-lying centring edge 150.

To illustrate the clamping system as a whole, FIG. 3 shows a collet nut 20. Sub-figure A shows an oblique view from above. The annular collet nut 20 is typically provided with an external thread (not shown here) or with an internal thread. On its upper side, the collet nut 20 is provided with a plurality of lugs 22 and grooves 21 lying therebetween. The lugs 22 show an undercut profile on their respective lateral flanks. In this exemplary embodiment, an undercut rectangular profile is designed on the side flanks of the lugs 22 or on the side flanks of the grooves 21.

In sub-figure B of FIG. 3, the conical area 25 formed inside the collet nut 20 can be seen, which is intended for the snug insertion of a collet. The view from above in sub-figure C of FIG. 3 shows the arrangement of the lugs 22 evenly distributed around the circumference of the annular collet nut 20.

FIG. 4 shows the operating tool 200 according to the invention as a socket in a further, particularly preferred embodiment. Sub-figure A shows an oblique view from below and sub-figure B shows a longitudinal section. The lower receiving area, having the lugs 102 and the grooves 101 lying therebetween, as well as the inner centring edge 150 and the centring ring 151, corresponds to the receiving area of the operating tool 100 shown in FIG. 2 in the form of a screwing aid.

The centring edge 150 prevents the collet nut from slipping from the socket in this embodiment of the operating tool 200 as a socket as well. The centring edge 150 therefore facilitates handling of the system and reduces the risk of injury.

In the case of the operating tool 200 shown in FIG. 4 in the form of a socket, a hexagon head 110 is also formed in the upper region of the operating tool. In this case, the hexagon head 110 in particular is used for connecting to a torque wrench for clamping and loosening a collet nut.

Between the region with the hexagon head 110 and the receiving area with the lugs 102, the operating tool 200 has a shaft 210. The shaft 210 has several elongated holes 211 (four elongated holes), which afford the operating person a view of the tool shaft located inside the socket when clamping of the collet.

Furthermore, the elongated holes 211 cause a reduction in materials, which minimises the weight of the operating tool 200.

As a further measure particularly for weight reduction, a circumferential taper 212 is provided in this embodiment, which is associated with a reduction in the wall thickness of the hollow cylindrical operating tool 200.

Sub-figure C of FIG. 4 shows a view from below in which the lugs 102, the grooves 101 lying therebetween, as well as the centring edge 150 are seen. Sub-figure D of Fig/ 4 shows a view of the operating tool from above onto the area with the hexagon head 110.

Sub-FIGS. A-D of 5 show various exemplary designs of the lugs 102 and the grooves 101 lying therebetween in the operating tool 100 according to the invention. In the embodiment shown here, the operating tool is a screwing aid. Accordingly, the operating tool can be designed as a socket, in particular as a torque nut, as in FIG. 4. The centring ring 151 pressed into the interior of the operating tool 100 is shown on the right in a sectional illustration, respectively. The edge of the centring ring 151 projecting on the side of the lugs 102 beyond the plane of the base surface of the grooves 101 forms the centring edge 150.

Sub-FIGS. A-I of 6 show various possible undercut profiles in the side flanks of the lugs 102 of the operating tool 100, 200 according to the invention. The respective undercut profile extends perpendicular to the radial orientation of the side flanks of the lugs 102.

For example, sub-figure C of FIG. 6 shows the particularly preferred rectangular profile. Sub-figure B of FIG. 6 shows the dovetail-shaped profile known from the prior art, and sub-figure A of FIG. 6 shows the S-profile known from the prior art.

The lugs of the respective collet nut are also preferably provided with the appropriate profile in order to achieve an optimal form fit. Under certain circumstances, however, certain deviations from the respective profiles may be tolerated.

FIG. 7 shows, in a view from below (sub-figure A) and in a longitudinal sectional view (sub-figure B), a wrench 300 with which a collet nut of the clamping system can be loosened or tightened by hand. The wrench has a handle 310, as well as a wrench head 320. The wrench head 320 is formed from a partially circular collar on which there are several lugs 302 as projections. In this exemplary embodiment, there are five lugs which are distributed evenly across the circumference of the partially circular collar. The lugs 302 are preferably designed with a corresponding undercut profile like the lugs of the respective collet nut and/or like the lugs of the respective operating tool according to the invention.

FIG. 8 shows a multi-part (modular) socket 400, which is formed from a base holder 420 and a changeable part (operating element) 410. The changeable part 410 comprises a terminal annular receiving area having a plurality of lugs 102 and grooves 101 lying therebetween, as well as an internal centring edge 150 according to the above description. The function of the modular socket 400 is comparable to the socket 200 that has been explained with reference FIG. 4. The corresponding elements of the modular socket 400 are provided with the same reference numerals.

The advantage of the modular socket 400 primarily lies in the fact that the changeable part 410 can be exchanged, for example if wear occurs, without the entire socket needing to be replaced. Furthermore, the modular socket 400 can be designed in such a way that various sizes of collet nut can be used due to corresponding sizes of the changeable part 410. Moreover, various sizes of the base holder 420 can be provided, so that, with such a modular system, all requirements can be covered in a cost-effective manner.

The changeable part 410 is connected to the base holder 420 via a cam threaded union connection 425. Sub-figure A shows the multi-part socket 400 in assembled form. Sub-figure B shows the base holder 420 and the changeable part 410 in separated form, wherein the cam 426 for the cam threaded union connection 425 is visible.

Sub-figure C of FIG. 8 shows a section view of the changeable part (operating element) 410. This depiction shows the centring ring 151 located inside the part 410. The centring ring 151 forms the centring edge 150.

FIG. 9 shows, in a comparable manner to FIG. 2, an embodiment of the operating tool 100 as a screwing aid. Unlike the embodiment of FIG. 2 that has an inner centring edge, the embodiment of FIG. 9 has an outer centring edge 250. The outer centring edge 250 in this embodiment is formed by an externally mounted, hollow cylindrical centring ring 251. In all other respects, the screwing aid shown in FIG. 9 corresponds to the screwing aid of FIG. 2 and reference is made to the embodiments of FIG. 2. An externally located centring edge 250 may also be used in the other embodiments explained above as an alternative to an internally located centring edge.

1. An operating tool for actuating a collet nut, wherein the operating tool has a terminal annular receiving area for gripping the collet nut and wherein the terminal annular receiving area comprises a plurality of grooves which run from the outside inwards and lugs that lie between the grooves, wherein the side flanks of the lugs delimited by the grooves are each provided with an undercut profile, wherein the terminal annular receiving area has a centring edge which protrudes beyond the plane of the base surface of the grooves.

2. The operating tool according to claim 1, wherein the centring edge is located in the inner region of the terminal annular receiving area.

3. The operating tool according to claim 1, wherein the centring edge is located in the outer region of the terminal annular receiving area.

4. The operating tool according to claim 1, wherein the undercut profile of the side flanks of the lugs is a rectangular profile.

5. The operating tool according to claim 1, wherein the operating tool is constructed from at least two parts and
(i) comprises a base body, which has the terminal annular receiving area having the grooves and the lugs, and
(ii) comprises a hollow cylindrical centring ring, which forms the centring edge and which extends into the interior of the base body or extends on the outer circumference of the base body.

6. The operating tool according to claim 5, wherein the centring ring is manufactured from stainless steel.

7. The operating tool according to claim 5, wherein the centring ring is pressed to fit snugly on an inner, annularly extending shoulder of the base body.

8. The operating tool according to claim 1, wherein the outer termination of the centring edge is located below the plane of the outer surfaces of the lugs.

9. The operating tool according to claim 1, wherein the end of the operating tool opposite the receiving area is provided with a hexagon head or a square socket.

10. The operating tool according to claim 1, wherein the operating tool is a socket.

11. The operating tool according to claim 10, wherein the socket is a torque nut.

12. The operating tool according to claim 10, wherein the socket is a multi-part socket, which comprises a base holder and a changeable part having the terminal annular receiving area and the centring edge.

13. The operating tool according to claim 12, wherein the changeable part is connected to the base holder by means of a threaded union connection.

14. The operating tool according to claim 1, wherein the operating tool is a screwing aid.

15. A clamping system for working with a collet, comprising at least one collet nut and at least one operating tool according to claim 1, in particular at least one screwing aid and/or at least one socket, as well as optionally at least one wrench for manually actuating the collet nut.
